(19) United States
(12) Patent Application Publication
(10) Pub. No.: US 2021/0280220 A1
(43) Pub. Date: Sep. 9, 2021

(54) SSD AND SSD SYSTEM

(71) Applicant: Silicon Motion, Inc., Hsinchu County (TW)

(72) Inventors: Chih-Chien Lin, New Taipei City (TW); Hung-Pin Tsai, New Taipei City (TW); Chien-An Chen, Hsinchu County (TW)

(21) Appl. No.: 17/158,023

(22) Filed: Jan. 26, 2021

Related U.S. Application Data
(60) Provisional application No. 62/984,303, filed on Mar. 3, 2020.

(51) Int. Cl. G11C 5/14; G06F 1/20; G06F 1/30; H05K 7/20

(52) U.S. Cl. CPC G11C 5/141; H05K 7/20163; G06F 1/30; G06F 1/20

(57) ABSTRACT

An SSD comprising: a circuit board; a first storage region, provided on a first side of the circuit board, comprising at least one first memory; a control region, provided on the first side, comprising at least one control IC for controlling the first memory; and first heat sink material, provided on the first storage region or the first control region.

### CROSS REFERENCE TO RELATED APPLICATIONS

This application claims the benefit of U.S. Provisional Application No. 62/984,303, filed on 2020 Mar. 3, the contents of which are incorporated herein by reference.

### BACKGROUND OF THE INVENTION

### 1. Field of the Invention

The present invention relates to an SSD (Solid State Disk) and an SSD system, and particularly relates to an SSD and an SSD system which has a heat dissipating mechanism.

### 2. Description of the Prior Art

In recent years, the SSD becomes more and more popular, since it has a high accessing speed. However, the SSD may generate much heat when it operates, since the SSD has many components operating at a high speed. Therefore, the SSD needs a proper heat dissipating mechanism.

### SUMMARY OF THE INVENTION

Therefore, one embodiment of the present invention is to provide an SSD having a heat dissipating mechanism.

Another embodiment of the present invention is to provide an SSD system having an SSD with a heat dissipating mechanism.

One embodiment of the present invention provides an SSD comprising: a circuit board; a first storage region, provided on a first side of the circuit board, comprising at least one first memory; a control region, provided on the first side, comprising at least one control IC for controlling the first memory; and first heat sink material, provided on the first storage region or the first control region.

The above-mentioned SSDs can be inserted to a case of an SSD system. The SSD system can further comprise a control device provided in the same case. The control device is configured to control the SSDs.

In view of above-mentioned embodiments, the SSD or the SSD system provided by the present invention can have a proper heat dissipating mechanism for dissipating heat.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an SSD having no heat sink material provided thereon, according to one embodiment of the present invention.

FIG. 2-4 are schematic diagrams illustrating SSDs having heat sink material provided thereon, according to different embodiments of the present invention.

FIG. 5 is a schematic diagram illustrating an SSD having no heat sink material provided thereon, according to another embodiment of the present invention.

FIG. 6-7 are schematic diagrams illustrating SSDs having heat sink material provided thereon, according to different embodiments of the present invention.

FIG. 8 is a schematic diagram illustrating an SSD system having SSDs according to one embodiment of the present invention.

### DETAILED DESCRIPTION

Several embodiments are provided in following descriptions to explain the concept of the present invention. The term “first”, “second”, “third” in following descriptions are only for the purpose of distinguishing different one elements, and do not mean the sequence of the elements. For example, a first device and a second device only mean these devices can have the same structure but are different devices.

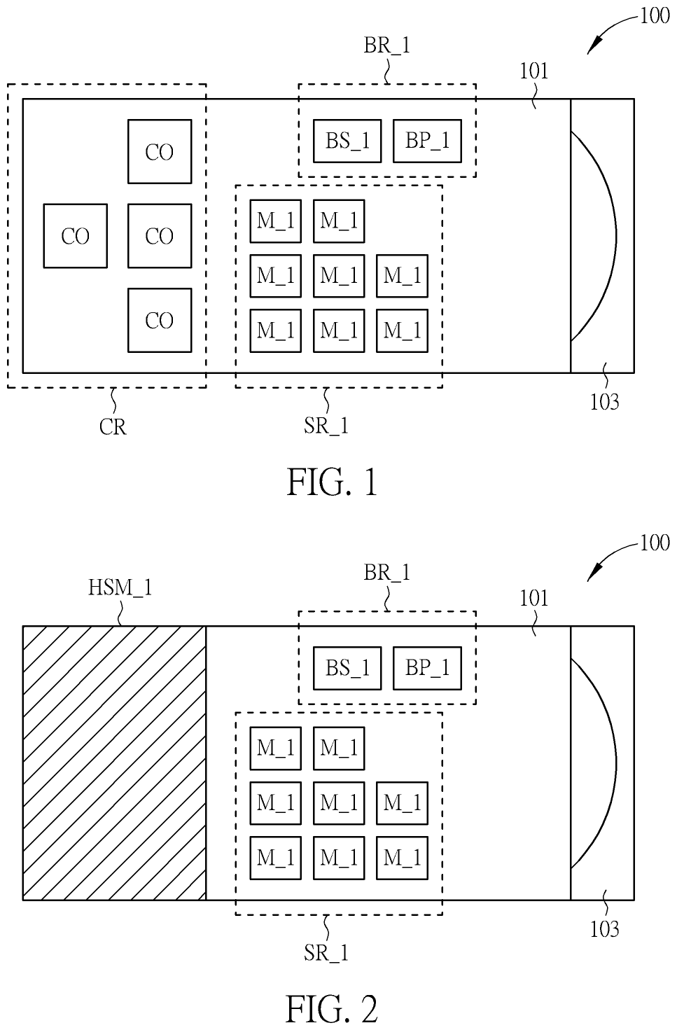

FIG. 1 is a schematic diagram illustrating an SSD 100 having no heat sink material provided thereon, according to one embodiment of the present invention. As illustrated in FIG. 1, the SSD 100 comprises a circuit board 101, a first storage region SR_1, a control region CR, and a first backup region BR_1. The first storage region SR_1, the control region CR and the first backup region BR_1 are provided on a first side of the circuit board 101. In one embodiment, the first backup region BR_1 can be omitted from the SSD 100. Also, in one embodiment, the SSD 100 further comprises an SSD carrier 103, which can be hold by a user to move the SSD 100.

The first storage region SR_1 comprises at least one first memory M_1, which can be NAND flash. The control region CR comprises at least one control IC (integrated circuit) CO for controlling the first memory M_1. Please note, the control ICs CO can be classified into more types of control ICs. For example, the control ICs CO can comprises a main controller, and other types of control ICs. The number and types of control ICs CO can be changed corresponding to different SSDs.

The first backup region BR_1 comprises a first backup power source BP_1 and a first backup storage region BS_1. The first backup power source BP_1 can be, for example, a capacitor. The first backup storage region BS_1 comprises at least one first backup storage device such as a DRAM. The SSD 100 uses power provided by the first backup power source BP_1 to backup data stored in the first backup storage device BS_1 to the first memory M_1 when the SSD 100 could not receive sufficient power from outside. For example, the SSD 100 is connected to an outside device such as a computer server, but the computer server could not provide sufficient power to the SSD 100 due to some reasons such as power failure. In such case, the SSD 100 uses power provided by the first backup power source BP_1 to backup data stored in the first backup storage device BS_1 to the first memory M_1. By this way, since the first memory M_1 is a memory which can keep data even if receives no power (e.g. a NAND), the necessary data can still be kept when the SSD 100 could not receive sufficient power from outside.

FIG. 2-4 are schematic diagrams illustrating SSDs having heat sink material provided thereon, according to different embodiments of the present invention. In the embodiment of FIG. 2, the first heat sink material HSM_1 is provided on the control region CR. The first heat sink material HSM_1 can be metal having a high thermal conductivity, for example, aluminum or copper. Also, the first heat sink material HSM_1 can be hard material such as a metal sheet. Additionally, the first heat sink material HSM_1 can be soft material such as thermal grease.

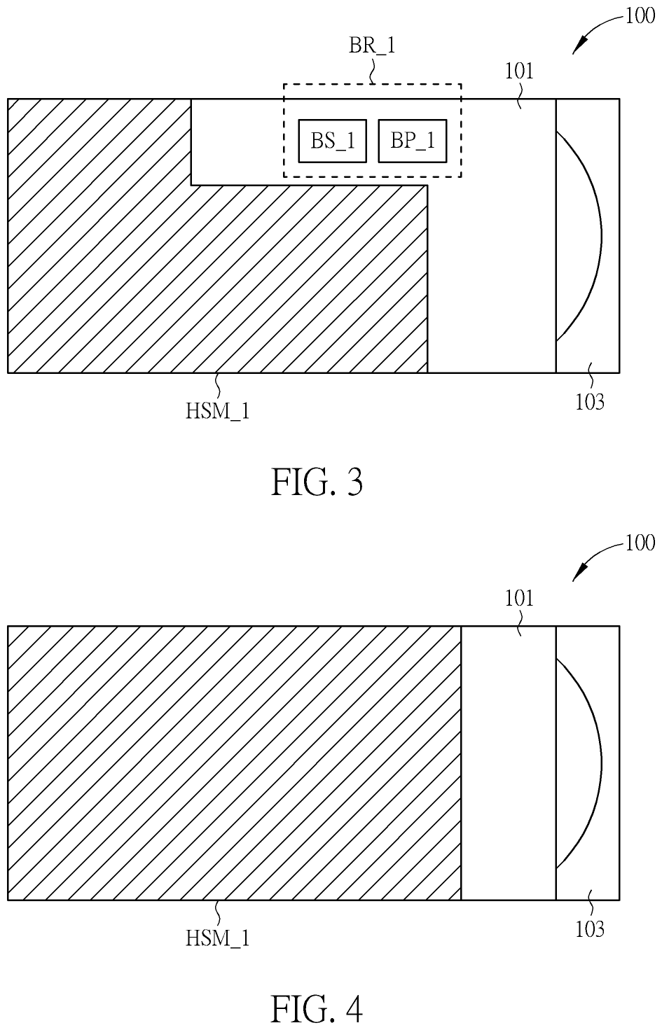

The first heat sink material HSM_1 is not limited to above-mentioned examples. Additionally, the first heat sink material HSM_1 can be provided on any other location of the SSD 100. For example, in the embodiment of FIG. 3, the first heat sink material HSM_1 is provided on the first storage region SR_1 and the control region CR. Furthermore, in the embodiment of FIG. 4, the first heat sink material HSM_1 is provided on the first storage region SR_1, the control region CR, and the first backup region BR_1.

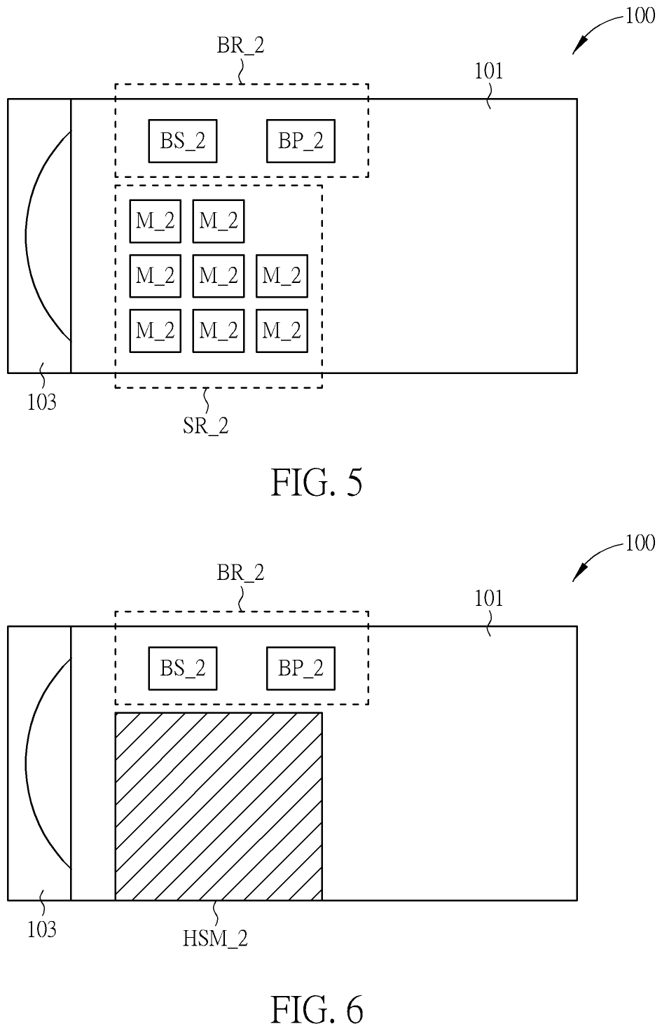

The components illustrated in FIG. 1 can be provided to another location of the SSD 100. FIG. 5 is a schematic diagram illustrating an SSD having no heat sink material provided thereon, according to another embodiment of the present invention. As illustrated in FIG. 5, the SSD 100 comprises a second storage SR_2 and a second backup region BR_2, which are provided on a second side of the circuit board 101. The second side of the circuit board 101 is opposite to a first side of the circuit board 101. The second storage region SR_2 comprises at least one second memory M 2, which can be a NAND flash.

The second backup region BR_2 comprises a second backup power source BP_2 and a second backup storage region BS_2. The second backup power source BP_2 can be a capacitor, and the second backup storage device BS_2 can be a DRAM. The SSD 100 uses power provided by the second backup power source BP_2 to backup data stored in the second backup storage device BS_2 to the second memory M 2.

In one embodiment, the SSD 100 can further comprise a shell to protect thereof. In such case, the shell is around the outermost of the circuit board 101, and the above-mentioned heat sink material is provided between the shell and the components (e.g. the control region CR, the first storage region SR_1 . . . ) on the circuit board 101.

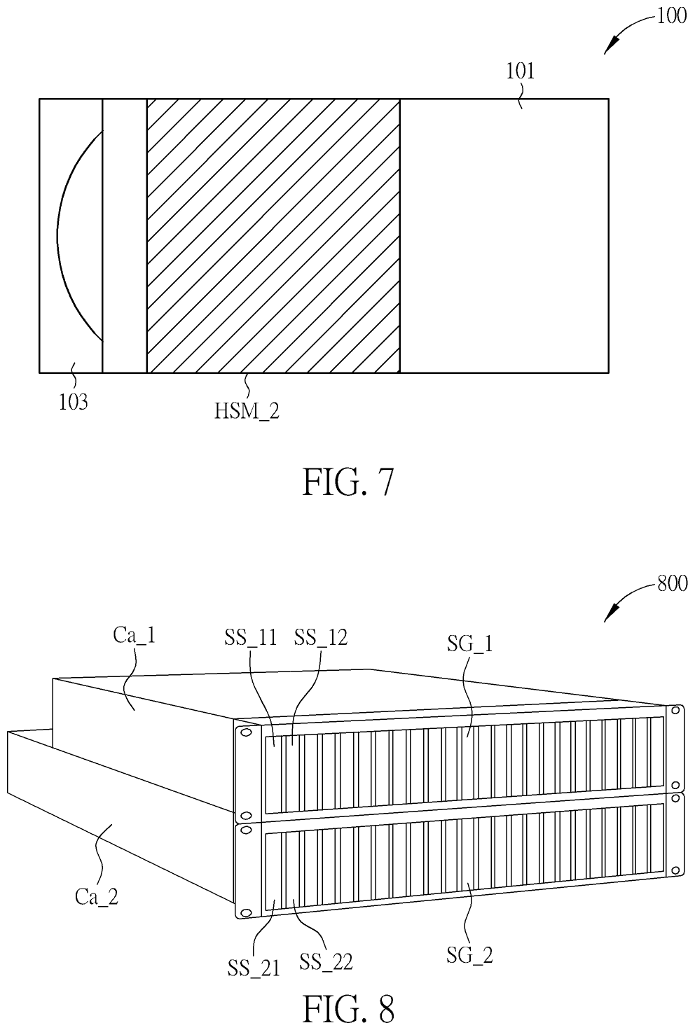

FIG. 6-7 are schematic diagrams illustrating SSDs having heat sink material provided thereon, according to different embodiments of the present invention. As illustrated in FIG. 6, the second heat sink material HSM_2 is provided on the second storage region SR_2. Also, in the embodiment of FIG. 7, the second heat sink material HSM_2 is provided on the second storage region SR_2 and the second backup region BR_2. Please note, in one embodiment, the SSD 100 can also comprise a control circuit provided on the second side of the circuit board 101. In such case, the second heat sink material HSM_2 can be provided on at least one of the second storage region SR_2, the second backup region BR_2 and the control circuit. For example, the second heat sink material HSM_2 can be provided on the second backup region BR_2 and the control circuit, or on the second storage region SR_2 and the second backup region BR_2.

FIG. 8 is a schematic diagram illustrating an SSD system 800 having SSDs according to one embodiment of the present invention. AS illustrated in FIG. 8, the SSD system 800 comprises a first case Ca_1, a second case Ca_2, a first SSD group SG_1 and a second SSD group SG_2. The first SSD group SG_1 comprises a plurality of first SSDs SS_11, SS_12 . . . (only two of them are marked) and the second SSD group SG_2 comprises a plurality of second SSDs SS_21, SS_22 . . . (only two of them are marked). The first SSDs SS_11, SS_12 . . . and the second SSDs SS_21, SS_22 . . . can comprise the structures illustrated in FIG. 1-FIG. 5. Therefore, a user can hold the SSD carrier 103 to insert the first SSDs SS_11, SS_12 . . . into the first case CA_1, and hold the SSD carrier 103 to insert the second SSDs SS_21, SS_22 . . . into the second case CA_2. Control devices of the first SSD group SG_1 and the second SSD group SG_2 can also be provided into the first case Ca_1 and the second case Ca_2. In one embodiment, the SSD system 800 can comprise only one case and only one SSD group. However, please note the SSD system provided by the present invention is not limited to the SSD system 800 illustrated in FIG. 8.

In view of above-mentioned embodiments, the SSD or the SSD system provided by the present invention can have a proper heat dissipating mechanism for dissipating heat.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An SSD (Solid State Disk), comprising:
a circuit board;
a first storage region, provided on a first side of the circuit board, comprising at least one first memory;
a control region, provided on the first side, comprising at least one control IC for controlling the first memory; and
first heat sink material, provided on the first storage region or the first control region.

2. The SSD of claim 1, wherein the first memory is a NAND flash.

3. The SSD of claim 1, wherein the first heat sink material is aluminum or copper.

4. The SSD of claim 1, further comprising:
a first backup power source, provided on the first side;
a first backup storage region, provided on the first side, comprising at least one first backup storage device;
wherein the SSD uses power provided by the first backup power source to backup data stored in the first backup storage device to the first memory when the SSD could not receive sufficient power from outside;
wherein the first heat sink material is further provided on the first backup power source or the first backup storage region.

5. The SSD of claim 4, wherein the first backup power source is a capacitor.

6. The SSD of claim 4, wherein the first backup storage device is a DRAM.

7. The SSD of claim 1, further comprising:
a second storage region, provided on a second side of the circuit board, comprising at least one second memory;
second heat sink material, provided on the second storage region.

8. The SSD of claim 7, wherein the second memory is a NAND flash.

9. The SSD of claim 7, further comprising:
a second backup power source, provided on the second side;
a second backup storage region, provided on the second side, comprising at least one second backup storage device;
wherein when the SSD could not receive sufficient power from outside, the SSD uses power provided by the second backup power source to backup data stored in the second backup storage device to the second memory;
wherein the second heat sink material is further provided on the second backup power source or the second backup storage region.

10. The SSD of claim 9, wherein the second backup power source is a capacitor and the second backup storage device is a DRAM.

11. An SSD system, comprising:
a case;
an SSD group, comprising at least SSD inserted into the case, wherein the SSD comprises:
an SSD, comprising:
a circuit board;
a first storage region, provided on a first side of the circuit board, comprising at least one first memory;
a control region, provided on the first side, comprising at least one control IC for controlling the first memory; and
first heat sink material, provided on the first storage region or the first control region; and
an control device, provided in the case, configured to control the SSDs.

12. The SSD system of claim 11, wherein the first memory is a NAND flash.

13. The SSD system of claim 11, wherein the first heat sink material is aluminum or copper.

14. The SSD system of claim 11, wherein the SSD further comprises:
a first backup power source, provided on the first side;
a first backup storage region, provided on the first side, comprising at least one first backup storage device;
wherein the SSD uses power provided by the first backup power source to backup data stored in the first backup storage device to the first memory when the SSD could not receive sufficient power from outside;
wherein the first heat sink material is further provided on the first backup power source or the first backup storage region.

15. The SSD system of claim 14, wherein the first backup power source is a capacitor.

16. The SSD system of claim 14, wherein the first backup storage device is a DRAM.

17. The SSD system of claim 11, wherein the SSD further comprises:
a second storage region, provided on a second side of the circuit board, comprising at least one second memory;
second heat sink material, provided on the second storage region.

18. The SSD system of claim 17, wherein the second memory is a NAND flash.

19. The SSD system of claim 17, wherein the SSD further comprises:
a second backup power source, provided on the second side;
a second backup storage region, provided on the second side, comprising at least one second backup storage device;
wherein when the SSD could not receive sufficient power from outside, the SSD uses power provided by the second backup power source to backup data stored in the second backup storage device to the second memory;
wherein the second heat sink material is further provided on the second backup power source or the second backup storage region.

20. The SSD system of claim 19, wherein the second backup power source is a capacitor and the second backup storage device is a DRAM.
